(19) United States
(12) Patent Application Publication
(10) Pub. No.: US 2018/0224924 A1
(43) Pub. Date: Aug. 9, 2018

(54) DEVICE AND METHOD OF OPERATION

(71) Applicant: Bartel Christiaan Dinger, Hamilton (NZ)

(72) Inventor: Bartel Christiaan Dinger, Hamilton (NZ)

(21) Appl. No.: 15/579,930

(22) PCT Filed: Jun. 2, 2016
(86) PCT No.: PCT/NZ2016/050092

§ 371 Date: Dec. 5, 2017

(30) Foreign Application Priority Data
Jun. 5, 2015 (NZ) 708880

(51) Int. Cl. G06F 1/32; G01R 27/26

(52) U.S. Cl. CPC G06F 1/3296; G01R 27/2605; G06F 1/3228

(57) ABSTRACT

The invention relates to a device using a sensor and a control system, which is configured to automatically change its state under certain conditions. The control system is configured to analyse measurement data derived from the sensor readings and to identify whether the device is in an operating environment or a non-operating environment. The control system will then cause the device to automatically enter into or revert to a particular mode of operation depending on the outcome of the analysis.

### FIELD OF THE INVENTION

The invention relates to a device configured to automatically activate or change functional state when one or more predetermined conditions are met and to a method for automatically activating or changing the functional state of the device when one or more predetermined conditions are met.

### BACKGROUND TO THE INVENTION

Powered electronic devices are successfully used in many fields, including in the agricultural industry for example. However, these devices often require a power supply, such as a battery for example, and generally cease to operate once the power is drained from the power supply, such as when a battery runs flat. To extend the useful life of a battery powered device before the battery needs to be recharged or replaced, it is useful to conserve the battery power as much as possible. This may be achieved by turning the device off when it is not in use and turning it on when it is ready to be used. However, the need for a user to turn the device on and/or off can cause the success of the power saving approach to be subject to human error, such as when a user neglects to turn the device on or off or fails to do so correctly. The incidence of human error may increase where numerous devices need to be turned on or off by a user at around the same time. It would be useful to provide an automatic and reliable way of ensuring that a device is turned on and in an operating mode when needed and/or that a device is turned off or in a low power consuming sleep mode when not needed.

Some forms of powered electronic devices may be used in environments that are exposed to water, such as devices that are used on agricultural animals, particularly animals that are farmed outside. It is important to the operation and longevity of these devices that the electronics are sealed to prevent water damage to sensitive electronics and power sources. However, where an electronic device has an external mechanically movable switch, it can be difficult to prevent water from entering into an electronic device through the opening provided for the switch.

In addition, mechanical switches may be relatively costly and susceptible to mechanical failure. Alternatives to mechanical switches, such as magnetic or mercury switches may provide a waterproof switching alternative, but require a user to activate the switch to power the device on or off. These types of switches may also be more expensive, bulky, and prone to failure, which can be a significant disadvantage in many applications.

It is therefore an object of the invention to provide a system and/or method for automatically activating and/or deactivating a device that goes at least some way toward overcoming the disadvantages of the prior art or that at least provide(s) the public with a useful choice.

### SUMMARY OF THE INVENTION

In a first aspect, the invention provides a powered device comprising at least one sensor and a control system, wherein the at least one sensor is configured to sense the capacitance of the environment within which the device is located and wherein the control system is configured to analyse capacitance measurement data derived from the at least one sensor readings to identify whether the device is likely to be in an operating environment or a non-operating environment and to cause the device to enter into or revert to a particular mode of operation depending on the outcome of the analysis.

In one form, the control system may be programmed to either cause:
a. the device to enter into or revert to an operating mode if the analysis of capacitance measurement data indicates that the device is likely to be in an operating environment;
b. the device to enter into or revert to a sleep mode if the analysis of capacitance measurement data indicates that the device is likely to be in a non-operating environment; or
c. the device to enter into or revert to an operating mode or a non-operating mode if the analysis of capacitance measurement data indicates that the device is likely to be in an operating environment or a non-operating environment respectively; or
d. the device to enter into a disabled mode in which the device is not operational.

Optionally, the control system is programmed to default to sleep mode after a predetermined time period.

In one form, when in sleep mode, the device wakes periodically and, when awake, causes the sensor to sense the capacitance of the environment.

Optionally, the control system causes the device to enter into the sleep mode if:
i. the capacitance measurement data or change in capacitance measurement data meets a predetermined threshold;
ii. the capacitance measurement data is below a predetermined threshold; or
iii. the capacitance measurement data or change in capacitance measurement data falls within a predetermined range.

In one form, the control system is configured to cause the device, when in sleep mode, to enter into the operating mode if:
i. the capacitance measurement data or change in capacitance measurement data meets a predetermined threshold;
ii. the capacitance measurement data is below a predetermined threshold; or
iii. the capacitance measurement data or change in capacitance measurement data falls within a predetermined range.

Optionally, the control system is configured to analyse capacitance measurements from the sensor over time to determine an average capacitance measurement, to identify when a change in that average capacitance measurement meets a predetermined threshold, and to then cause the device to change mode.

In one form, the control system is programmed to identify a change in capacitance that is derived from:
i. the difference between the capacitance measurement data of two consecutive readings by the sensor;
ii. the difference between the previous average capacitance measurement data and the new average capacitance measurement data; or
iii. the extent of capacitance measurement variation over a predetermined time period.

In one form, the control system is programmed to cause the device to enter into operating mode for a predetermined time period after the device is first activated.

Optionally, the control system is self-calibrating.

Optionally, the device is configured to enter into sleep mode when it is enveloped by an electrostatic discharge package and to enter into operating mode when the package is opened.

In one form, the control system is programmed to cause the device to enter into sleep mode after a predetermined time period has passed following initial activation of the device.

Optionally, the sensor is a capacitive sensor that sensors the capacitance of the environment within which the device is located.

In one form, the control system may be programmed to either cause:
i. the device to enter into or revert to an operating mode if the analysis of measurement data indicates that the device is likely to be in an operating environment;
ii. the device to enter into or revert to a sleep mode if the analysis of measurement data indicates that the device is likely to be in a non-operating environment; or
iii. the device to enter into or revert to an operating mode or a non-operating mode if the analysis of measurement data indicates that the device is likely to be in an operating environment or a non-operating environment respectively; or
iv. the device to enter into a disabled mode in which the device is not operational.

In one form, the control system causes the device to enter into the sleep mode if:
i. the measurement data or change in measurement data meets a predetermined threshold;
ii. the measurement data is below a predetermined threshold; or
iii. the measurement data or change in measurement data falls within a predetermined range.

Optionally, the control system is configured to cause the device, when in sleep mode, to enter into the operating mode if:
i. the measurement data or change in measurement data meets a predetermined threshold;
ii. the measurement data is below a predetermined threshold; or
iii. the measurement data or change in measurement data falls within a predetermined range.

In a second aspect, the invention provides a method of conserving the power of a powered device according to the first aspect of the invention, the method comprising the steps of placing the device within an electrostatic discharge package and sealing the package to cause the device to enter into the sleep mode.

Optionally, when the powered device is stored within an electrostatic discharge package, the method further comprises the step of opening the package.

In one form, the device is configured to be activated after the device is removed from the package.

Also disclosed herein is a powered device comprising a capacitive sensor and a control system, wherein the sensor is configured to sense capacitance of the environment within which the device is located and wherein the control system is configured to cause the device to default to a sleep mode in which the device wakes periodically and, when awake, causes the sensor to sense the capacitance of the environment; and wherein if the environment measurement meets a predetermined threshold, the control system causes the device to adopt an operation mode, and if the environment measurement is below the predetermined threshold, the control system causes the device to adopt the sleep mode.

Preferably, the control system is configured to analyse measurements from the sensor over time to determine an average capacitance value and to identify a sudden shift from that average value.

Preferably, the control system is programmed to cause the device to enter into operating mode for a predetermined time period after the device is first activated.

Preferably, the control system is self-calibrating.

Preferably, the device is configured to enter into sleep mode when it is enveloped by an anti-static package and to enter into operating mode when the package is opened.

In a second aspect, the invention provides a method of conserving the power of a powered device according to the first aspect of the invention, the method comprising the steps of placing the device within an anti-static package and sealing the package to cause the device to enter into the sleep mode.

In a third aspect, the invention provides a method of activating a powered device according to the first aspect of the invention when the powered device is stored within an anti-static package, the method comprising the steps of opening the package. Optionally, the device is configured to be activated after the device is removed from the package.

To assist with understanding the invention, the following explanations and definitions are provided.

The term “comprising” as used in this specification means “consisting at least in part of”. When interpreting each statement in this specification that includes the term “comprising”, features other than that or those prefaced by the term may also be present. Related terms such as “comprise” and “comprises” are to be interpreted in the same manner.

The term “indicates” and the related term “indication” as used in the specification is intended to mean “likely”. For example, where data from a sensor indicates that a device is in an operating environment, it is not a conclusive determination that the device is in fact in an operating environment, but the device is likely to be in an operating environment.

The term “sleep mode” as used in the specification is intended to mean, unless the context suggests otherwise, a mode of operation in which the device is turned on, but is in a state in which the device draws little power. The device is caused to ‘wake’ periodically for the sensor to periodically sense the capacitance of the environment in which the device is located and for the control system to periodically analyse data from the sensor. During sleep mode, the device uses less power than during operating mode. The parameters of the sleep mode may be programmed into the device, such as by programming the control system of the device.

The term “operating mode” as used in this specification is intended to mean, unless the context suggests otherwise, a mode of operation in which the sensor and control system are substantially constantly operating at the level required for the device when it is in use. The parameters of the operating mode may be programmed into the device, such as by programming the control system of the device.

The term “operating environment” as used in this specification is intended to mean, unless the context suggests otherwise, any environment outside of an electrostatic discharge (anti-static) package.

This invention may also be said broadly to consist in the parts, elements and features referred to or indicated in the specification of the application, individually or collectively, and any or all combinations of any two or more said parts, elements or features, and where specific integers are mentioned herein which have known equivalents in the art to which this invention relates, such known equivalents are deemed to be incorporated herein as if individually set forth.

The invention consists in the foregoing and also envisages constructions of which the following gives examples only.

### BRIEF DESCRIPTION OF THE DRAWINGS

Preferred embodiments of the invention will be described by way of example only and with reference to the drawings, in which:

FIG. 1 is a flow diagram of one form of operating method for one form of device of the invention from the moment of manufacture;

FIG. 2 is a flow diagram of a typical operating method for one form of device of the invention;

FIG. 3 is a flow diagram of a typical operating method for another form of device of the invention; and

FIG. 4 is a flow diagram of a typical operating method for yet another form of device of the invention.

### DETAILED DESCRIPTION OF PREFERRED EMBODIMENTS

### General Overview

The invention relates to a powered device that is configured to identify whether the device is in an operating environment or a non-operating environment and to cause the device to enter into or revert to a particular mode of operation accordingly. The device may be specially configured to automatically switch from one mode to another mode, such as from a sleep mode to an operating mode, once the device is removed from an enclosed surrounding, such as a package/housing.

The invention also relates to a method of operating the device.

### System Components

In one form, the device comprises at least one sensor for measuring the capacitance of the surrounding environment in which the device is located. The sensor may be any sensor suitable for measuring the capacitance of the environment. For example, the sensor may be a capacitive sensor or a near field sensor.

The device of the invention may also comprise a control system, electrically connected to the sensor. For example, the sensor and control system may both be mounted on a PCB and connected electrically in the usual manner.

The control system comprises a data processor for processing data received from at least one sensor. The control system may be programmable or it may be loaded with one or more existing operating programs.

The control system may also comprise a clock to time the frequency at which measurement data is taken by the sensor(s) and/or to control the time period for which the device may remain in a particular mode, such as an operating mode, a sleep mode, a test mode, a non-sensing mode, or a disabled mode.

In one form, the control system may comprise a programmable microprocessor comprising a memory, data processor, and a clock.

The device also comprises a power supply. The power supply may be any suitable power supply provided on the device. For example, the power supply may comprise one or more batteries or slow release capacitors. In another form, the power supply may come from a slow release capacitor, or from a power supply that harnesses a renewable energy, such as solar energy or kinetic energy. The power supply is electrically connected to the sensor and the control system.

The sensor is configured to measure the capacitance of the surrounding environment of the device and to then send the sensor measurements (sensor readings) to the control system as measurement data or as signals that are converted to capacitance measurement data by the control system. The control system is programmed to analyse capacitance measurement data derived from the sensor readings.

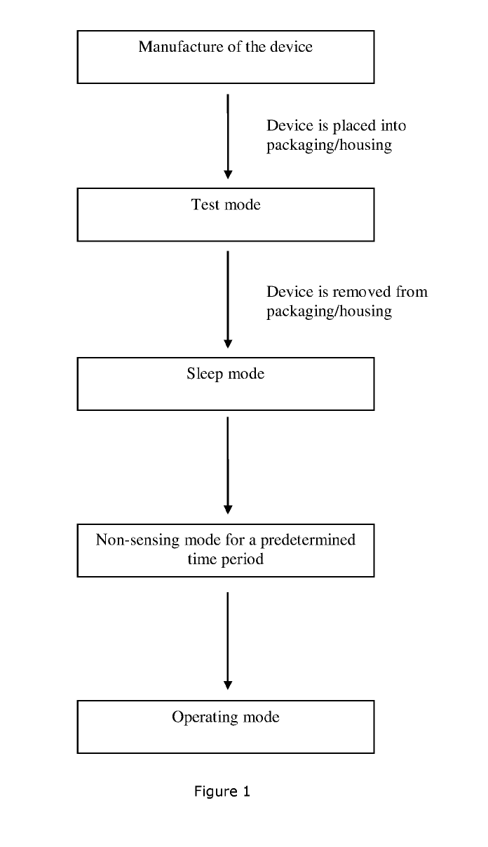

Depending on the analysis of the capacitance measurement data, the control system may cause the device to adopt a particular mode of operation, such as an operating mode or a sleep mode, as will be described below and as shown in FIGS. 1 to 3.

Therefore, the device of the invention may be programmed to:
i. automatically enter into sleep mode when analysis of the capacitance measurement data indicates that the device is in a non-operating environment; or
ii. automatically enter into operating mode when the analysis of the capacitance measurement data indicates that the device is in an operating environment; or
iii. automatically enter into sleep mode when analysis of the capacitance measurement data indicates that the device is in a non-operating environment and to automatically enter into operating mode when the analysis of the capacitance measurement data indicates that the device is in an operating environment.

### Examples of Devices and Methods of the Invention

In one form, the control system is programmed to cause the device to default to an operating mode after the device is first activated (powered up) after manufacture. In another form, the control system is programmed to cause the device to enter into operating mode at or after a predetermined period of time. In another form, the device may comprise an operating mode user input, such as a switch, which may be activated to cause the device to enter into operating mode at a desired time. In some forms, the device may be programmed to default to or enter into operating mode and may also comprise an operating mode user input to override the programme.

In one form, the control system may be programmed to keep the device in the operating mode for a predetermined period of time, such as 12 hours. In operating mode, the device typically draws its full operating current.

In one form, the control system may be programmed to cause the device to default to sleep mode after the device is first activated after manufacture. In one form, the control system is programmed to cause the device to enter into sleep mode at or after a predetermined period of time. In another form, the device may comprise a sleep mode user input, such as a switch, which may be activated to cause the device to enter into sleep mode at a desired time. In some forms, the device may be programmed to default to or enter into sleep mode and may also comprise a sleep mode user input to override the programme.

Optionally, the control system is programmed to keep the device in sleep mode for a predetermined period of time or indefinitely until the capacitive environment changes enough to trigger a state change.

In the sleep mode, the device is powered on, but is in a state in which the device draws only a small amount of current. The device may be configured to remain in sleep mode until it is caused to enter into another type of mode, such as an operating mode, or until the device is turned off or runs out of power. In the sleep mode, the device uses less power than when it is in operational mode because the peripheral applications necessary for normal operating function can be temporarily disabled, leaving just the minimum sensor(s) and peripherals necessary to wake periodically and analyse the measurement data.

In one form, as shown in FIG. 1, the control system may be programmed to provide the device with a ‘test mode’. The control system may be configured so that in the test mode, which occurs when the device is activated for the first time during manufacture, any lights provided on the device, such as LED's, may be caused to flash as a check to see that the lights are functional.

In one form, the control system may be programmed to lock the device in a “non-sensing” mode for a predetermined period of time. For example, after a device of the invention is removed from its enclosed surrounding, such as from an electro-static discharge package or housing, the device will automatically switch to an operating mode after the control system identifies that the device is in an operating environment. The control system may be configured to cause the device to then enter into a non-sensing mode for a certain time period or the control system may be configured to cause the device to immediately enter into a non-sensing mode for a certain time period after the control system identifies that the device is in an operating environment. By causing the device to enter into a non-sensing mode for a certain period of time, such as 1-24 hours for example, and preferably 6-8 hours, the device is able to be handled by humans and positioned in its operating location without working the sensor(s) of the device unnecessarily, which would disadvantageous drain the power of the device and may create false readings from the sensor(s). Where the device is a reproductive state indicator to be attached to a bovine and also includes one or more sensors to sense the reproductive activity of the bovine, the ability of the device to enter into a non-sensing mode means that inaccurate data or noise created by people handling the device may be avoided.

The various ways in which the device can automatically change its mode will now be described.

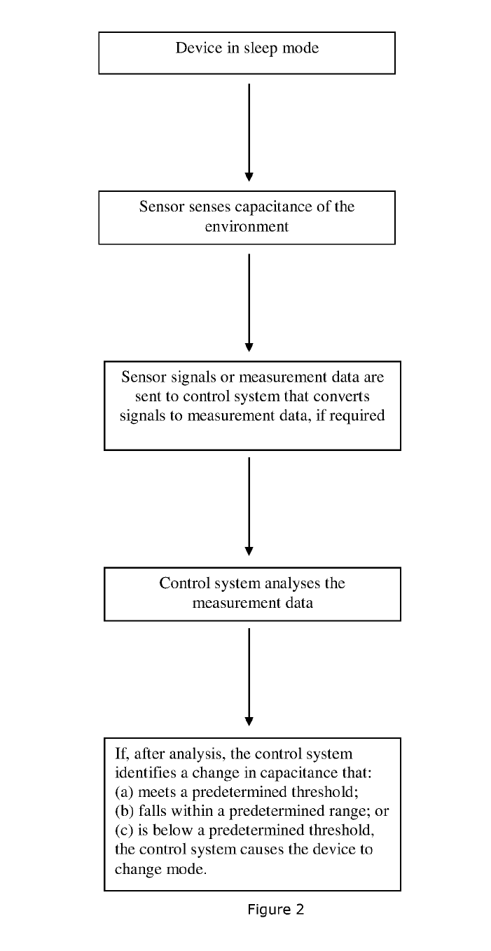

In one form, as shown in FIG. 2, the control system is programmed to cause the device to automatically change from sleep mode into operating mode when an analysis of the capacitance measurement data indicates that the device is in an operating environment. In this form, the control system is programmed to cause the device to ‘wake’ periodically during sleep mode, such as every second, for a short period of time, such as 1 millisecond for example. Each time that the device wakes, the sensor measures the capacitance (such as the relative permittivity) of the environment in which the device is located and the control system analyses the measurement data derived from the sensor readings. This process may continue until the control system determines that the device is in an operating environment and causes the device to enter into operating mode, or until the device is powered off (such as by a switch or by power loss, for example). In one form, the sensor may continue periodically measuring the capacitance of the environment indefinitely and the control system may continue analysing the measurement data indefinitely, even when the device is in operating mode.

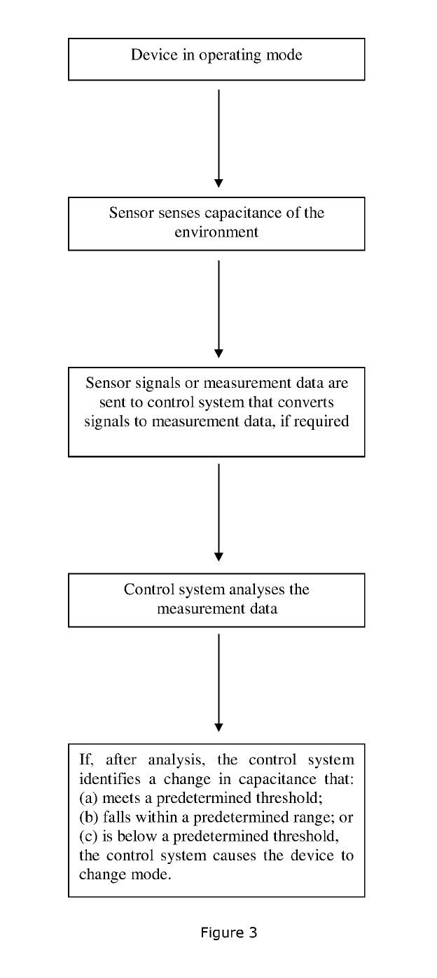

In one form, as shown in FIG. 3, the control system may be programmed to cause the device to automatically enter into or revert to sleep mode when the analysis of measurement data indicates that the device is in a non-operating environment. For example, the sensor may sense the capacitance of the environment in which the device is located and the control system may, after analysis of the sensor readings, determine that the device is in a non-operating environment. The control system may then cause the device to automatically enter into sleep mode immediately or to enter into sleep mode after a predetermined period of time. In one form, the control system may be programmed to cause the device to enter into sleep mode after the measurement data substantially consistently indicate, for a predetermined period of time, that the device is in a non-operating environment. For example, if 8 out of the last 10 readings from the sensor(s) indicate that the device is in a non-operating environment, the control system may cause the device to enter into sleep mode.

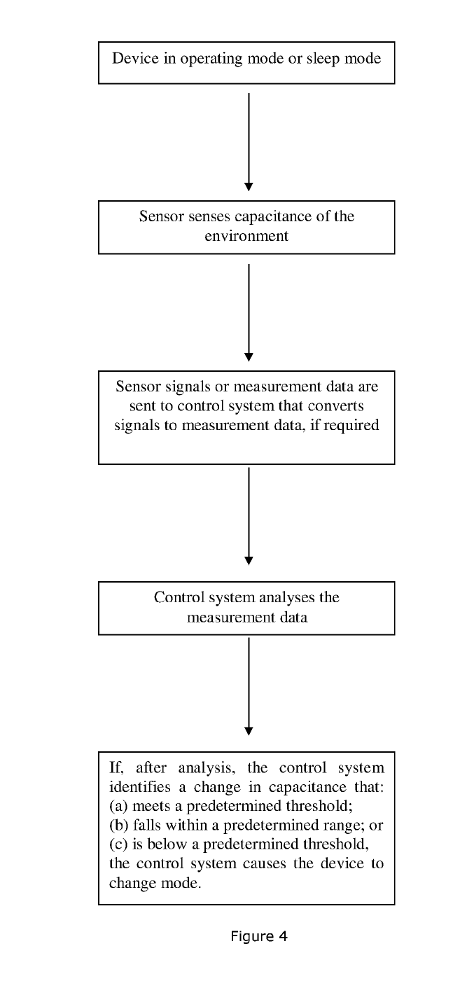

In one form, as shown in FIG. 4, the control system may be programmed to cause the device to change between operating mode and sleep mode depending on whether an analysis of the measurement data indicates that the device is in an operating or non-operating environment respectively.

In one form, the control system may be programmed to cause the device to enter into a disabled mode after the device has been in an operating mode for a predetermined period of time, such as for 1,000 hours for example, and the device then senses that it is in a non-operating environment. In the disabled mode, the device is not operational. For example, the control system may cause the device to switch off, so as to draw no electric current, or the control system may cause the device to enter into sleep mode but the control system will not automatically convert the device to an operating mode even if an analysis of the measurement data indicates that the device is in an operating environment. In this form of the invention, the control system may be programmed to cause the device to be permanently disabled, or the control system may be programmed to allow the device to be reset by a particular input, such as by using a particular password, code, or other system or method that might be known only to the proprietor or supplier of the device. In this form, it may be possible to prevent an operational device from being returned to a non-operating environment (such as by being sealed in an electrostatic discharge package) and onsold. This form of the invention may be particularly useful for a manufacturer who wants to ensure that any product sold under its brand is new and/or has at least undergone appropriate operational testing before being sold and used.

### Examples of Methods for Identifying the Environment of the Device

The control system is programmed to identify the likely environment in which the device is located. The control system identifies the likely environment by analysing measurement data from the sensor.

For the sake of simplicity, embodiments of the invention will be described using a capacitive sensor that measures the capacitance of the environment within which the device is located. However, it should be appreciated that other suitable sensors that measure the capacitance of the device environment may be used instead without departing from the scope of the invention. For example, one or more near field sensors may be used instead of or in combination with a capacitive sensor.

In one form, the control system is programmed to receive signals from a sensor, such as a capacitive sensor. Any signals are converted to measurement data derived from the sensor readings. The measurement data derived from a capacitive sensor will include capacitance data, which may also be referred to herein as capacitance measurement data. In another form, the signals may be converted to measurement data by a data converter, which then sends the measurement data to the control system.

In one form, the device may comprise other types of sensor that may help the control system to identify whether the device is in an operating or non-operating environment. For example, the device may comprise a capacitive sensor and a temperature sensor. In this form, the temperature readings from the temperature sensor will be converted to measurement data. Other forms of sensor that may be used with the device may include a noise sensor or movement sensor, such as an accelerometer, for example.

The control system is programmed to compare the measurement data to identify a change in capacitance or in the environment that indicates that the device has moved from an operating environment to a non-operating environment or vice versa. Additionally, or alternatively, the control system is programmed to average the measurement data, such as capacitance data, over time and to compare the previous average with the new average as new data is analysed. In one form, the control system begins averaging the measurement data/capacitance data after the data values reach a substantially steady state. Alternatively, the control system may begin averaging the measurement data/capacitance data after two or more data values are received by the control system.

The control system may be programmed to compare previous and new measurement data/capacitance data (whether averaged or not) and to identify a change in capacitance that meets one or more predetermined conditions. Where the control system is programmed to identify a change in the average capacitance, the control system may be configured to analyse the data for a change in the average capacitance value across a predetermined number of data values and/or within a predetermined time period.

When the predetermined condition(s) is/are met, the control system identifies that the environment of the device has changed and the control system will cause the operating mode of the device to change accordingly.

In one form, the control system may be programmed to recognise a change in capacitance that meets (is at or above) a predetermined threshold. The change in capacitance may be derived from:
(i) the difference between the capacitance data of two consecutive readings by the sensor;
(ii) the difference between the previous average capacitance data value and the new average capacitance data value; or
(iii) the extent of capacitance variation over a predetermined time period (i.e. the extent of creep over time).

In some forms, the control system may be programmed to recognise any two or more of the options i to iii. For example, if the change between the two consecutive capacitance data values meets a predetermined threshold, the control system may recognise that a change of mode may be required. If, for example, the device is in sleep mode and the change in capacitance meets a predetermined threshold (say, when the new capacitance is x % higher or lower than the previous capacitance), the control system may cause the device to enter into the operating mode. Conversely, if the device is in operating mode and the change in capacitance meets a predetermined threshold (such as when the new capacitance is x % higher or lower than the previous capacitance), the control system may cause the device to enter into the sleep mode.

Additionally or alternatively, the control system may be programmed so that if the capacitance data meets a predetermined threshold or is within a predetermined range, the control system will cause the device to adopt the operating mode or the sleep mode based on the capacitance value. In one form, the control system may be programmed to cause the device to change mode when the capacitance data (which may be a single data value or an average data value) is below a predetermined threshold. For example, where the capacitance data meets (is at or over) the predetermined threshold, the control system may cause the device to enter into or revert to the operating mode. Conversely, where the control system recognizes that the capacitance data is below the predetermined threshold, the control system may cause the device to enter into or revert to sleep mode.

In any of the above embodiments, the predetermined thresholds, values, and ranges programmed into the control system may be different depending on whether the device is in the operating mode or in the sleep mode.

In one form, the control system may be programmed to analyse different forms of measurement data to identify whether the environment of the device has changed. For example, the control system may be programmed to analyse capacitance data and temperature data so that a capacitance measurement, or a change in capacitance or change in average capacitance, beyond a predetermined threshold together with a temperature measurement, or a change in temperature or average temperature, beyond a predetermined threshold may cause the control system to identify that the device has entered into an operating or non-operating environment, as the case may be.

In one form, the control system is programmed to be self-calibrating, so that as more capacitance values are received, the control system may adjust the values, thresholds, and/or ranges at which the control system will cause the device to change mode. In this way, the device can account for pressure and temperature changes and other variables that may alter the capacitance of the environment.

In any of the above embodiments, the control system may be programmed to issue an alert if the measurement data value or the change in measurement data (such as the capacitance data) is above or below a predetermined threshold or falls within a predetermined range, which may indicate that the device is faulty.

In some forms, the control system may recognise a significant change in measurement data, such as a significant change in capacitance, but may not cause the device to change mode. For example, the device may comprise a capacitive sensor and the control system may be programmed so that when the sensor provides capacitance data measurements within a first range X, the control system will cause the device to enter into or revert to operating mode and when the sensor provides data measurements within a second range Y (where the values in range Y do not overlap with the values in range X), the control system causes the device to enter into or revert to sleep mode. In this form, the device may be subjected to environmental changes that cause a significant shift in capacitance, but the capacitance data may indicate that the device should remain in operating mode or in sleep mode, as the case may be, unless the data measurements change to fall within the other range. The control system may also be programmed to issue an alert if the capacitance data falls outside these ranges, which may indicate that the device is faulty.

In one form, when the device is not in use, such as when it is in storage or is being transported to a new location, the device may be placed within an electrostatic discharge package, made from electrostatic discharge material. The package is then enveloped with the device inside. The package is configured to form a Faraday cage around the device once the package is enveloped. Optionally, the device is enveloped and sealed within the package.

The electrostatic discharge package may be a bag, box, container, wrap or any other form of electrostatic discharge packaging or housing (packaging that has anti-static qualities). Therefore, the package may be any item that is capable of forming a sealed or substantially sealed environment around the device. Preferably, the package comprises electrostatic discharge protective packaging, which may include bubble packaging, to prevent damage to the device when it is stored or in transit.

Where the device is configured to enter into sleep mode at or after a predetermined time period, the device may be placed within an electrostatic discharge package before or after it enters into sleep mode. If not already in sleep mode, the device will enter into sleep mode at or after the predetermined time period.

Conversely, in one form, the device may be placed within an electrostatic discharge package when it is in operating mode, even if the device is not programmed to enter into sleep mode at or after a predetermined time period. In this embodiment, the control system may be programmed to cause the one or more sensors, including a capacitance sensor or the like, to periodically or continuously sense the environment of the device, even though the device is in operating mode. The environment within the package, when closed, has a different capacitance to the external environment. Therefore, once the package envelops the device, the capacitance sensor will sense a change in capacitance and this change will be identified by the control system when analysing data from the sensor(s). The control system may be programmed to recognise that the change in capacitance indicates a change in the environment of the device and may even be programmed to identify that the device is now in a non-operating environment (such as if the new capacitance value(s) or average value meet(s) a predetermined threshold or fall(s) within a predetermined range of values that indicate a non-operating environment). After identifying a change in the environment or identifying that the device is in a non-operating environment, the control system may then cause the device to enter into sleep mode.

In one form, when in sleep mode, the sensor(s) continue(s) sensing the environment of the device periodically when the device wakes. Once the package is opened, the environment of the device changes. The change of environment causes a sudden variation in the capacitance measurements sensed by the capacitance sensor. The capacitance measurements are sent from the capacitance sensor to the control system and are analysed by the control system. Again, the control system may be programmed to recognise that the change in capacitance indicates a change in the environment of the device and may even be programmed to identify that the device is now in an operating environment (such as if the new capacitance value(s) or average value meet(s) a predetermined threshold or fall(s) within a predetermined range of values that indicate an operating environment). After identifying a change in the environment or identifying that the device is in an operating environment, the control system may then cause the device to enter into operating mode.

In one form, the control system may be configured so that the device is only caused to enter into operating mode by input from a user, which may be the activation of a switch on the device by the user or it may be the user causing a remote activation signal to be sent to the control system from a separate controller, such as a computer.

In another form, the control system may be programmed to recognise capacitance measurement data that indicates that the device is within a substantially stable capacitance environment and to then cause the device to enter into sleep mode. In this form, the control system may be programmed to average the capacitance measurement data over time so that a substantially constant average is reached within the steady state environment. Alternatively, the control system may be programmed to identify when the capacitance measurement data is substantially steady, such as when consecutive data values do not vary by more than x % and/or when the data values do not vary by more than x % across a predetermined time period. When the control system identifies that the device is in a substantially steady state environment, the control system may cause the device to enter into sleep mode.

To prevent the device from entering into sleep mode when in a steady state operating environment, the control system may be programmed to only cause the device to enter into sleep mode if the steady state capacitance measurement data values meet predetermined conditions that indicate that the device is in a non-operating environment or if other sensors indicate that the device is in a non-operating environment. Examples of predetermined conditions include steady state capacitance measurement data that falls above or below a predetermined threshold; or that falls within a predetermined range of typical data values that indicate that the device is in a non-operating environment. Examples of other measurement data from other sensors that indicate that the device is in a non-operating environment may be a sudden temperature drop or increase, such as a temperature change exceeding x % within a predetermined period of time, such as 1 to 60 seconds for example.

The device of the invention may be suitable for many uses, including agricultural uses. The device may be particularly suitable for use as a device that senses the reproductive activity of bovines, such as cows.

### Advantages

As can be seen from the embodiments of the invention described above, the device of the invention and the method of using the device can reduce power consumption by causing the device to enter into sleep mode when the device is in a non-operating environment and is unlikely to be used. The reduced power consumption provides the advantage of extending the life of the device before the power supply needs to be replaced or recharged.

Because the device and method of the invention allow the device to be automatically activated by entering into operating mode when the control system indicates that the device is likely to be in an operating environment, there is less risk that the device may not operate when expected to. For example, known devices may require a switch to be turned on by a person before the device becomes operational. Where that person is in control of turning on numerous devices, there is an increased risk that the user may overlook one or more of the devices and so the devices may be placed in an operating environment but not turned on.

The device of the invention also avoids the risk that the device could be inadvertently switched off, such as if the device is placed on an animal and the animal rubs against a surface so that the mechanical switch is contacted and turned off.

Another advantage of the invention not requiring a mechanical switch to project from the device is that the device of the invention is less susceptible to damage, which can otherwise result because of the switch mechanism becoming broken or the switch being broken off the device.

The device of the invention may also offer the advantage of being sealed so as to be watertight or of at least having a watertight activation and de-activation system. For example, by holding the electronics, such as the control system, within a watertight housing in the device or by making the entire device watertight, it is possible to avoid the risk of water damage to the sensitive electronic components. In particular, where the device of the invention uses capacitive sensing to switch the device between an operating mode and a sleep mode or a disabled mode, it is possible to create a watertight device that can be used in an outdoor environment with minimal risk to the electronic components of the device. Therefore, the invention may provide a powered electronic device that is configured to be activated and/or deactivated and may be used operationally in outdoor environments or wet indoor environments in a manner that avoids or at least mitigates the risk of water or other fluids entering into the device and damaging the electronics. Contrast this with devices that require a mechanical switch to be activated to turn the device on or off and through which water/liquids may enter into and damage the device.

The device of the invention may also be smaller than typical devices because the automatic activation system of the invention means that the device does not require bulky switches to turn it off or on. The ability to reduce the size of the device increases the applications in which the device may be used. For example, the device may be used in medical applications or veterinary applications where smaller sensing or imaging devices are preferred.

In some forms, the device of the invention may also be more cost effective than devices requiring mechanical activation and deactivation switches. For example, in some known devices, six soldering points are used to attach a mechanical switch to a printed circuit board. The solder, switch, and labour each add to the cost of the device.

### Examples of Use of the Device of the Invention

As mentioned above, the device of the invention may be used as a sensing device in the agricultural field. For example, the device may further comprise a touch sensor or other forms of sensor to sense reproductive activity in a bovine. For this use, many devices may be placed within a single package. After purchase, a farmer or other user may open the package so that the devices in the package are automatically activated and may enter into operating mode or into non-sensing mode for a certain period of time. Because the farmer may be placing hundreds of devices on bovines on the same day, the ability of the device of the invention to automatically activate without requiring the farmer to turn the device on with a switch avoids the risk that the farmer may neglect to turn on one or more devices. It also saves the farmer a significant amount of time.

The individual devices are then placed on individual bovines to sense the reproductive activity of that bovine. The farmer may handle the device significantly as the device is taken from the package and attached to a bovine. Therefore, it can be advantageous for the device to be in a non-sensing mode during this time and to enter into an operating mode shortly afterwards. The control system may be programmed to cause the device to automatically convert from the non-sensing mode to the operating mode after a certain time period, such as 2-8 hours for example.

The device of the invention may be suitable for many different uses. For example, the device may be configured to be used as a hearing aid, such as a disposable hearing aid. In this form, the device may be configured so that when the operating device is returned to an electro-static discharge package, which may be a special box or housing for example, the control system identifies that the device is now in a non-operating environment and causes the device to enter into sleep mode. When the device is next removed from the package/housing, the control system identifies that the device is in an operating environment and causes the device to enter into operating mode.

In another form, the device may be suitable for use as a ‘pill cam’ in which the device comprises a camera and is swallowed by a patient so that internal imaging of the patient's digestive system can be obtained.

The device may be suitable for these uses because it can be activated without requiring a mechanical switch; because the electronics can be kept waterproof within the device; and because the size of the device can be made reasonably small.

It should be appreciated that the various uses for the device of the invention are numerous and should not be limited to these examples only.

### General

Embodiments of the invention may be implemented by hardware, software, firmware, middleware, microcode, or any combination thereof. When implemented in software, firmware, middleware or microcode, the program code or code segments to perform the necessary tasks may be stored in a machine-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The various illustrative logical blocks, modules, circuits, elements, and/or components described in connection with the examples disclosed herein may be implemented or performed with a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general purpose processor may be a microprocessor, but in the alternative, the processor may be any conventional processor, controller, microcontroller, circuit, and/or state machine. A processor may also be implemented as a combination of computing components, e.g., a combination of a DSP and a microprocessor, a number of microprocessors, one or more microprocessors in conjunction with a DSP core, or any other such configuration.

The methods or software algorithms described in connection with the examples disclosed herein may be embodied directly in hardware, in a software module executable by a processor, or in a combination of both, in the form of a processing unit, programming instructions, or other directions, and may be contained in a single device or distributed across multiple devices. A software module may reside in RAM memory, flash memory, ROM memory, EPROM memory, EEPROM memory, registers, hard disk, a removable disk, a CD-ROM, or any other form of storage medium known in the art. A storage medium may be coupled to the processor such that the processor can read information from, and write information to, the storage medium. In the alternative, the storage medium may be integral to the processor.

One or more of the components and functions illustrated in the figures may be rearranged and/or combined into a single component or embodied in several components without departing from the invention. Additional elements or components may also be added without departing from the invention. Additionally, the features described herein may be implemented in software, hardware, as a business method, and/or combination thereof.

In its various aspects, the invention can be embodied in a computer-implemented process, a machine (such as an electronic device, or a general purpose computer or other device that provides a platform on which computer programs can be executed), processes performed by these machines, or an article of manufacture. Such articles can include a computer program product or digital information product in which a computer readable storage medium containing computer program instructions or computer readable data stored thereon, and processes and machines that create and use these articles of manufacture.

The foregoing description of the invention includes preferred forms thereof. Modifications may be made thereto without departing from the scope of the invention.

1. A package comprising an electrostatic discharge material wherein at least one powered device is located within the package and comprises at least one sensor and a control system, wherein the at least one sensor is configured to sense the capacitance of the environment within which the device is located and wherein the control system is programmed to analyze capacitance measurement data derived from the at least one sensor reading to:
(a) identify whether the device is likely to be in a non-operating environment, in which the package is sealed, or an operating environment, in which the package is open; and
(b) cause the device to enter into or revert to a non-operating or sleep mode if the analysis of capacitance measurement data indicates that the device is likely to be in a non-operating environment; and
(c) cause the device to enter into or revert to an operating mode if the analysis of capacitance measurement data indicates that the device is likely to be in an operating environment.

2. The package according to claim 1, wherein the control system is programmed to cause:
the device to enter into a disabled mode in which the device is not operational after the device has been in the operating mode for a predetermined period of time.

3. (canceled)

4. The package according to claim 1, wherein, when in the sleep mode, the device wakes periodically and, when awake, causes the sensor to sense the capacitance of the environment.

5. The package according to claim 1, wherein the control system is programmed to cause the device to enter into the sleep mode if:
i. the capacitance measurement data or change in capacitance measurement data is above a predetermined threshold;
ii. the capacitance measurement data is below a predetermined threshold; or
iii. the capacitance measurement data or change in capacitance measurement data falls within a predetermined range.

6. The package according to claim 1, wherein the control system is programmed to cause the device, when in the sleep mode, to enter into the operating mode if:
i. the capacitance measurement data or change in capacitance measurement data is above a predetermined threshold;
ii. the capacitance measurement data is below a predetermined threshold; or
iii. the capacitance measurement data or change in capacitance measurement data falls within a predetermined range.

7. The package according to claim 1, wherein the control system is programmed to analyze capacitance measurements from the sensor over time to determine an average capacitance measurement, to identify when a change in that average capacitance measurement meets a predetermined threshold, and to then cause the device to change mode.

8. The package according to claim 1, wherein the control system is programmed to identify a change in capacitance that is derived from:
i. the difference between the capacitance measurement data of two consecutive readings by the sensor;
ii. the difference between the previous average capacitance measurement data and the new average capacitance measurement data; or
iii. the extent of capacitance measurement variation over a predetermined time period.

9. The package according to claim 1, wherein the control system is programmed to cause the device to enter into the operating mode for a predetermined time period after the device is first activated.

10-11. (canceled)

12. The package according to claim 1, wherein the control system is programmed to cause the device to enter into the sleep mode after a predetermined time period has passed following initial activation of the device.

13. The package according to claim 1, wherein the sensor is a capacitive sensor that senses the capacitance of the environment within which the device is located.

14. A method of conserving the power of controlling the activation of the package of claim 13 comprising a plurality of the powered devices, the method comprising the steps of placing the plurality of powered devices within a package comprising an electrostatic discharge material and sealing the package to cause the plurality of powered devices to enter into the sleep mode and to remain in the sleep mode until either the package is opened or the package is opened and the plurality of devices are removed from the package to cause the plurality of devices to automatically enter into the operating mode.

15-16. (canceled)

17. The package according to claim 1, wherein the control system is programmed to cause the device to enter into a non-sensing mode after a predetermined time period has passed following initial activation of the device and to then enter into the operating mode after a predetermined time period has passed.

18. The package according to claim 1, wherein, the control system is self-calibrating.

19. A powered device configured to sense the reproductive status of bovines and to be packaged within a package comprising an electrostatic discharge material, wherein the device comprises at least one sensor and a control system, wherein the at least one sensor is configured to sense the capacitance of the environment within which the device is located and wherein the control system is programmed to analyze capacitance measurement data derived from the at least one sensor readings to:
(a) identify whether the device is likely to be in a non-operating environment, in which the package is sealed, or an operating environment, in which the package is open;
(b) cause the device to enter into or revert to a non-operating or sleep mode if the analysis of capacitance measurement data indicates that the device is likely to be in a non-operating environment; and
(c) cause the device to enter into or revert to an operating mode if the analysis of capacitance measurement data indicates that the device is likely to be in an operating environment.

20. The powered device according to claim 19, wherein the control system is programmed to cause the device to enter into a disabled mode in which the device is not operational after the device has been in the operating mode for a predetermined period of time.

21. The powered device according to claim 19, wherein, when in the sleep mode, the device wakes periodically and, when awake, causes the sensor to sense the capacitance of the environment.

22. The powered device according to claim 19, wherein the control system is programmed to cause the device to enter into the sleep mode if:
i. the capacitance measurement data or change in capacitance measurement data meets a predetermined threshold;
ii. the capacitance measurement data is below a predetermined threshold; or
iii. the capacitance measurement data or change in capacitance measurement data falls within a predetermined range.

23. The powered device according to claim 19, wherein the control system is programmed to cause the device, when in the sleep mode, to enter into the operating mode if:
i. the capacitance measurement data or change in capacitance measurement data meets a predetermined threshold;
ii. the capacitance measurement data is below a predetermined threshold; or
iii. the capacitance measurement data or change in capacitance measurement data falls within a predetermined range.

24. The powered device according to claim 19, wherein the control system is programmed to analyze capacitance measurements from the sensor over time to determine an average capacitance measurement, to identify when a change in that average capacitance measurement meets a predetermined threshold, and to then cause the device to change mode.

25. The powered device according to claim 19, wherein the control system is programmed to identify a change in capacitance that is derived from:
i. the difference between the capacitance measurement data of two consecutive readings by the sensor;
ii. the difference between the previous average capacitance measurement data and the new average capacitance measurement data; or
iii. the extent of capacitance measurement variation over a predetermined time period.

26. The powered device according to claim 19, wherein the control system is programmed to cause the device to enter into the operating mode for a predetermined time period after the device is first activated.

27. The powered device according to claim 19, wherein the control system is programmed to cause the device to enter into the sleep mode after a predetermined time period has passed following initial activation of the device.

28. The powered device according to claim 19, wherein the control system is programmed to cause the device to enter into a non-sensing mode after a predetermined time period has passed following initial activation of the device and to then enter into the operating mode after a predetermined time period has passed.

29. The powered device according to claim 19, wherein, the control system is self-calibrating.

30. The powered device according to claim 19, wherein the sensor is a capacitive sensor that sensors the capacitance of the environment within which the device is located.
